(19) United States
(12) Patent Application Publication
(10) Pub. No.: US 2026/0033328 A1
(43) Pub. Date: Jan. 29, 2026

(54) POWER CONVERSION APPARATUS

(71) Applicant: HITACHI ASTEMO, LTD., Hitachinaka-shi, Ibaraki (JP)

(72) Inventors: Rinnosuke ODA, Hitachinaka-shi, Ibaraki (JP); Toshiaki ISHII, Hitachinaka-shi, Ibaraki (JP); Naoya TOKOO, Hitachinaka-shi, Ibaraki (JP)

(73) Assignee: HITACHI ASTEMO, LTD., Hitachinaka-shi, Ibaraki (JP)

(21) Appl. No.: 18/993,251

(22) PCT Filed: Jul. 28, 2022
(86) PCT No.: PCT/JP2022/029210

§ 371 Date: Jan. 10, 2025

(51) Int. Cl. H01L 23/367; H01L 23/29; H01L 23/31

(52) U.S. Cl. CPC H01L 23/367; H01L 23/295; H01L 23/3107

(57) ABSTRACT

A power conversion apparatus is a semiconductor apparatus including: a semiconductor module in which a semiconductor element and the heat exchanger plate connected to the semiconductor element are molded and sealed with resin; and a thermal conductive material having a semisolid shape disposed between the semiconductor module and a cooling member that cools the semiconductor module, in which a thickness of the resin between the thermal conductive material and the heat exchanger plate is larger than a thickness of the thermal conductive material.

### TECHNICAL FIELD

The present invention relates to a power conversion apparatus.

### BACKGROUND ART

In a double-sided cooling type power conversion apparatus, in the process of soldering a lead frame of a semiconductor module, overmolding occurs in a state where dimensional variations of members, variations in parallelism between members at the time of bonding, and the like occur. However, since it is necessary to consider the low thermal conductivity of this overmolded resin, it is necessary to grind the resin part to expose the surface of a heat exchanger plate, and this causes variation in the height of a plurality of semiconductor modules arranged on the board. Therefore, there is a demand for an apparatus that eliminates such variation in height and further improves reliability.

For example, PTL 1 described below discloses a configuration of a semiconductor module in which a thermal interface material (TIM) is disposed as a thermal conductive material to absorb such variation in height, thereby achieving both absorption of the variation and improvement of heat dissipation.

### CITATION LIST

### Patent Literature

PTL 1: WO 1999/16128 A

### SUMMARY OF INVENTION

### Technical Problem

Conventionally, when the TIM is thickened to absorb the height variation of the apparatus, pump out of the TIM occurs, and thus, there is a concern about a decrease in reliability. In view of this, an object of the present invention is to provide a power conversion apparatus that suppresses pump out and achieves improvement in productivity, improvement in reliability, and cost reduction.

### Solution to Problem

A power conversion apparatus is a semiconductor apparatus including: a semiconductor module in which a semiconductor element and the heat exchanger plate connected to the semiconductor element are molded and sealed with resin; and a thermal conductive material having a semisolid shape disposed between the semiconductor module and a cooling member that cools the semiconductor module, in which a thickness of the resin between the thermal conductive material and the heat exchanger plate is larger than a thickness of the thermal conductive material.

### Advantageous Effects of Invention

It is possible to provide a power conversion apparatus that suppresses pump out and achieves improvement in productivity, improvement in reliability, and cost reduction.

### BRIEF DESCRIPTION OF DRAWINGS

FIG. 1 is an overall cross-sectional view of a power conversion apparatus according to one embodiment of the present invention.

FIG. 2 is a view illustrating a thickness of a thermal conductive material and a mount cross-sectional view of a plurality of power conversion apparatuses.

FIG. 3 is a first modification.

Hereinafter, an embodiment of the present invention will be described with reference to the drawings. The following description and drawings are examples for describing the present invention, and are omitted and simplified as appropriate for the sake of clarity of description. The present invention can be carried out in various other forms. Unless otherwise specified, each constituent element may be singular or plural.

The positions, sizes, shapes, ranges, and the like of the constituent elements illustrated in the drawings do not always represent actual positions, sizes, shapes, ranges, and the like, for the sake of easy understanding of the invention. Therefore, the present invention is not necessarily limited to the positions, sizes, shapes, ranges, and the like disclosed in the drawings.

### One Embodiment of Present Invention and Overall Configuration of Apparatus

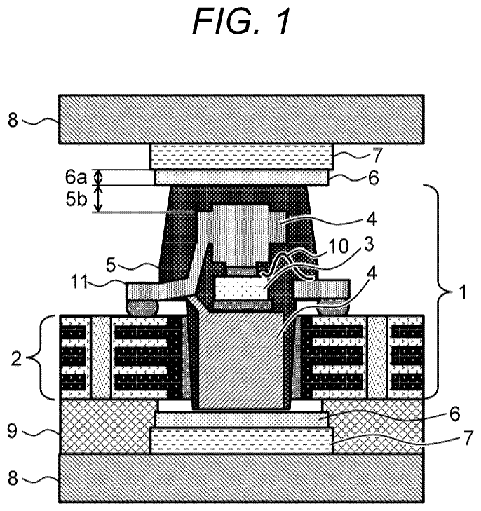

### FIG. 1

A power conversion apparatus includes a semiconductor module 1 having both surfaces sandwiched by cooling water channels 8 (cooling members 8). The semiconductor module 1 includes a semiconductor chip 3 (semiconductor element 3) and a heat exchanger plate 4 (lead frame 4) connected to the semiconductor chip 3, and the semiconductor chip 3 and the heat exchanger plate 4 are molded and sealed by a resin 5.

A thermal conductive material 6 having a semisolid shape is disposed between the semiconductor module 1 and each of the cooling water channels 8 on the upper and lower surfaces. The thermal conductive material 6 is, for example, a TIM. The semiconductor module 1 is in contact with the thermal conductive material 6 on the upper and lower surfaces in FIG. 1. Each of the thermal conductive material 6 is in contact with an insulation sheet 7 on a surface opposite to a surface in contact with the semiconductor module 1. The insulation sheet 7 is in contact with the cooling water channel 8 on a surface opposite to a surface in contact with the thermal conductive material 6.

Both surfaces of the semiconductor chip 3 are connected to the heat exchanger plate 4 via solder. Note that the connection between the semiconductor chip 3 and the heat exchanger plate 4 is not limited to solder, and for example, a sintered material, a hybrid material of metal and resin, or the like may be used. A gate pad on the upper surface side of the semiconductor chip 3 and a lead terminal 11 are connected by a wire 10.

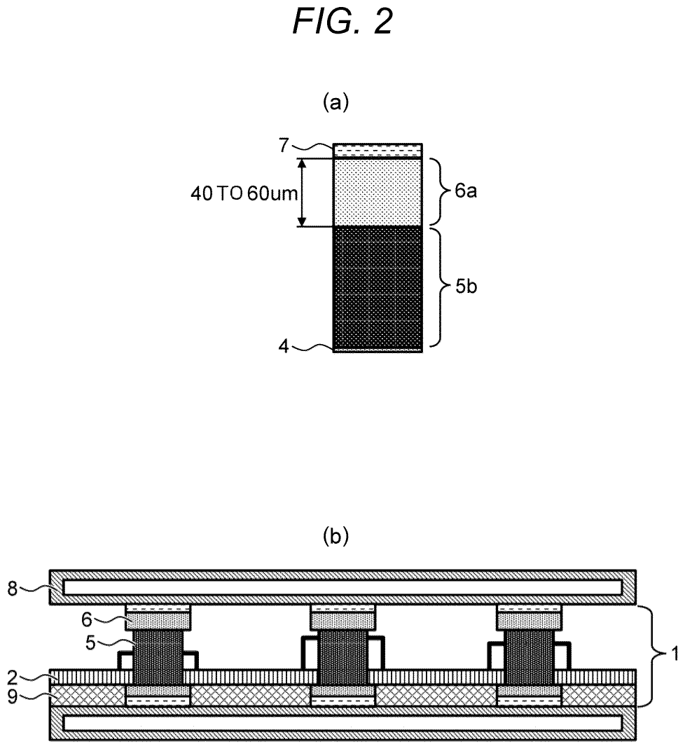

The lead terminal 11 of the semiconductor module 1 is connected to a printed circuit board 2 (hereinafter, board 2) by solder. The board 2 is mounted with the semiconductor module 1, and is assembled by sandwiching the cooling water channel 8 in which the thermal conductive material 6 and then insulation sheet 7 are attached to this semiconductor module 1 from both of the upper and lower sides. Note that although a single semiconductor module 1 mounted on the board 2 is illustrated in FIG. 1, actually, as illustrated in FIG. 2(b) described later, a plurality of semiconductor modules 1 are arranged side by side on the board 2, and the thermal conductive material 6 having a semisolid shape is disposed between each semiconductor module 1 and the cooling water channel 8 installed on the upper and lower surfaces.

The semiconductor module 1 is provided with overmold sealing by the resin 5 such that the mold resin 5 having a predetermined thickness is disposed between the heat exchanger plate 4 and the thermal conductive material 6. The mold resin 5 has high thermal conductivity. A thickness 5b of the resin 5 between the thermal conductive material 6 and the heat exchanger plate 4 is larger than a thickness 6a of the thermal conductive material 6.

The thickness 6a of the thermal conductive material 6 is set within a range of 40 μm to 60 μm inclusive when a TIM containing an alumina filler generally used for the thermal conductive material 6 is used. This thickness 6a is thinner than the thickness of the conventional thermal conductive material 6, and thus contributes to cost reduction. Since the thickness 6a of the thermal conductive material 6 is thinner than the conventional one, the thermal resistivity is improved and the cooling performance is improved.

The reason why the TIM used as the thermal conductive material 6 is set within a limited range as described above is that it is a thickness of the thermal conductive material 6 in which the TIM is difficult to pump out. The TIM generally has a region called bond line thickness (BLT) in which the film thickness does not change significantly even when applied with a certain load or more, and the bond line thickness is determined by the size of a filler contained in the TIM. By using this nature, in order to thin the TIM to a bond line thickness that is difficult to pump out and to suppress pump out, if the thickness is in the range of 40 μm to 60 μm or less, it is possible to suppress the possibility that the thermal conductive material 6 pumps out. Since the TIM is more expensive than the resin 5 that is thermally conductive, it is possible to achieve both cost reduction and improvement in cooling performance by performing such limitation.

The mold resin 5 is a cured epoxy resin obtained by curing an epoxy compound together with a curing agent. Note that in order to achieve high thermal conductivity of the cured epoxy resin, the resin 5 may be a modified epoxy compound having high thermal conductivity, or may contain one or more types of fillers having high thermal conductivity to increase the amount of the filler. This improves the cooling performance of the semiconductor module 1.

Examples of the filler material contained in the resin 5 include silica powder such as fused silica, talc, aluminum powder, mica, clay, calcium carbonate, and graphite. These filler materials may be used in combination, and the thermal conductivity of the resin 5 may be improved by changing the particle size.

The mold resin 5 does not need to cover the entire surface of the heat exchanger plate 4, and may be disposed so as to partially cover the heat exchanger plate 4 with the mold resin 5, for example, as in a resin burr. In general, when a resin burr exists, the thermal resistance increases and the cooling performance decreases, and thus it is necessary to remove the resin burr by grinding or the like. However, in the present invention, since the thermal resistance of the mold resin 5 itself is low, the resin burr can be applied as it is without grinding.

### FIG. 2

FIG. 2(a) is a view illustrating a difference in thickness between the thermal conductive material 6 and the mold resin 5 formed between the insulation sheet 7 and the heat exchanger plate 4, and FIG. 2(b) is a view illustrating the plurality of semiconductor modules 1 mounted on the board 2.

As illustrated in FIG. 2(a), in the configuration of the present invention, as described above, the thermal conductive material 6 is set within a range of 40 μm to 60 μm or less. The resin 5 is set to more than 55% and 260% or less of the thermal conductivity of the thermal conductive material 6. The reason for this is to maintain the thermal conductive material 6 of the present invention at a thermal resistance value equal to or higher than the thickness and the thermal conductivity of the thermal conductive material 6 conventionally applied. Therefore, in the present invention, the thickness of the thermal conductive material 6 is set to be thinner than the conventional one, and the resin 5 is set to be thicker than the thermal conductive material 6. For example, when the thermal conductive material 6 is 3 W/m·K, the thermal conductivity of the mold resin 5 having high thermal conductivity is set to 3·6 W/m·K or more.

As illustrated in FIG. 2(b), when the plurality of semiconductor modules 1 are arranged on the board 2, even if there is variation in the height of each heat exchanger plate 4, the resin 5 formed by overmolding can absorb the variation. Due to this, the thermal conductive material 6 can be formed to have a constant thickness and to be thinner than the conventional one, and therefore pump out can be suppressed.

In this manner, in the power conversion apparatus of the present invention, since the resin 5 obtained by overmolding the heat exchanger plate 4 absorbs the variation in the height of the heat exchanger plate 4, it is possible to omit the grinding process of the resin 5 for overmolding, which has been conventionally performed, and it is also possible to control the mold resin 5 with high accuracy by die molding, and therefore productivity is improved and cost can be reduced. By disposing the resin 5 thicker than the thermal conductive material 6 by overmolding, the height of each heat exchanger plate 4 does not vary, and the thermal conductive material 6 that does not need to absorb the height variation can be made thin and constant to the bond line thickness that is less likely to pump out, and therefore pump out of the thermal conductive material 6 can be suppressed. This improves reliability of the power conversion apparatus.

### First Modification

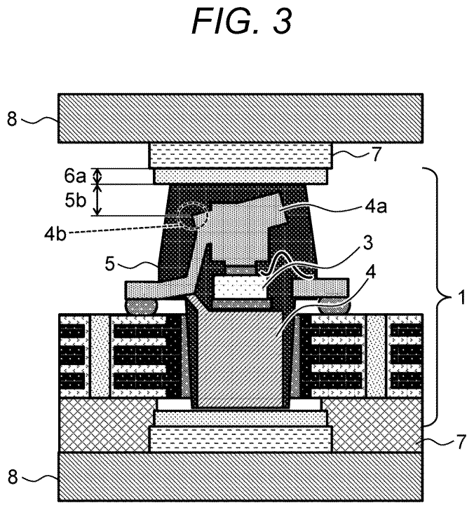

### FIG. 3

As illustrated in FIG. 3, the surfaces of the heat exchanger plate 4 and the thermal conductive material 6 need not be arranged in parallel, and by applying the present invention, the semiconductor module 1 can be manufactured without being affected by the fact that the respective surfaces are not parallel. When the thickness of the mold resin 5 is not constant from an inclination degree of the heat exchanger plate 4, the length in the vertical direction from the upper surface (surface in contact with the thermal conductive material 6 on the upper side) of the resin 5 overmolded with the heat exchanger plate 4 to an end portion 4b of the maximum distance in the heat exchanger plate 4 is defined as the thickness 5b of the mold resin 5. By doing this, the heat exchanger plate 4 and the thermal conductive material 6 can achieve the same effects as in the case where the respective surfaces are parallel.

According to one embodiment of the present invention described above, the following operational effects are achieved.
(1) A semiconductor apparatus includes: the semiconductor module 1 in which the semiconductor element 3 and the heat exchanger plate 4 connected to the semiconductor element 3 are molded and sealed with the resin 5; and the thermal conductive material 6 having a semisolid shape disposed between the semiconductor module 1 and the cooling member 8 that cools the semiconductor module 1, in which the thickness of the resin 5 between the thermal conductive material 6 and the heat exchanger plate 4 is larger than the thickness of the thermal conductive material 6. This can provide a power conversion apparatus that suppresses pump out and achieves improvement in productivity, improvement in reliability, and cost reduction.
(2) The plurality of semiconductor modules 1 are mounted on the board 2, and the thermal conductive material 6 having the semisolid shape is disposed between each of the plurality of semiconductor modules 1 and the cooling member 8. By doing this, height variation can be eliminated by resin overmold, the amount of the thermal conductive material 6 (TIM) disposed on the semiconductor module 1 can be made thin and constant, and pump out can also be suppressed.
(3) The thickness of the thermal conductive material 6 is in a range of 40 μm to 60 μm. This contributes to cost reduction and improves cooling performance.
(4) The thermal conductivity of the resin 5 is higher than the thermal conductivity of the thermal conductive material 6. By doing this, the resin 5 can be formed thicker than the thermal conductive material 6 while keeping the thermal resistance value equal or greater, and pump out can be suppressed.
(5) The thermal conductivity of the resin 5 is more than 55% and 260% or less of the thermal conductivity of the thermal conductive material 6. By doing this, the resin 5 can be formed thicker than the thermal conductive material 6 while keeping the thermal resistance value equal or greater, and pump out can be suppressed.
(6) The resin 5 is an epoxy compound or contains at least one type of filler material. By doing this, the resin 5 having high thermal conductivity is used, and the cooling performance is improved.

Note that the present invention is not limited to the above embodiment, and various modifications and other configurations can be combined without departing from the gist of the present invention. The present invention is not limited to one including all the configurations described in the above embodiment, and includes one in which a part of the configuration is deleted.

### REFERENCE SIGNS LIST

1 semiconductor module
2 printed circuit board (board)
3 semiconductor chip
4 heat exchanger plate (lead frame)
4a inclined heat exchanger plate
4b surface end portion of heat exchanger plate farthest from thermal conductive material
5 mold resin
5b thickness of mold resin
6 thermal conductive material
6a thickness of thermal conductive material
7 insulation sheet
8 cooling water channel
9 heat dissipation sheet
10 wire bonding
11 lead terminal

1. A power conversion apparatus that is a semiconductor apparatus, comprising:
a semiconductor module in which a semiconductor element and the heat exchanger plate connected to the semiconductor element are molded and sealed with resin; and
a thermal conductive material having a semisolid shape disposed between the semiconductor module and a cooling member that cools the semiconductor module, wherein
a thickness of the resin between the thermal conductive material and the heat exchanger plate is larger than a thickness of the thermal conductive material.

2. The power conversion apparatus according to claim 1, wherein
a plurality of the semiconductor modules are mounted on a board, and
the thermal conductive material having the semisolid shape is disposed between each of the plurality of semiconductor modules and the cooling member.

3. The power conversion apparatus according to claim 1, wherein
the thickness of the thermal conductive material is in a range of 40 μm to 60 μm.

4. The power conversion apparatus according to claim 1, wherein
thermal conductivity of the resin is higher than thermal conductivity of the thermal conductive material.

5. The power conversion apparatus according to claim 4, wherein
thermal conductivity of the resin is more than 55% and 260% or less of thermal conductivity of the thermal conductive material.

6. The power conversion apparatus according to claim 1, wherein
the resin is an epoxy compound or contains at least one type of filler material.
